(19) United States
(12) Patent Application Publication
(10) Pub. No.: US 2011/0315077 A1
(43) Pub. Date: Dec. 29, 2011

(54) TEMPLATE, MANUFACTURING METHOD, AND PROCESSING METHOD

(76) Inventor: Masafumi ASANO, Kanagawa (JP)

(21) Appl. No.: 13/051,729

(22) Filed: Mar. 18, 2011

(30) Foreign Application Priority Data
Jun. 25, 2010 (JP) 2010-145238

(51) Int. Cl. B05C 11/00; B05D 5/00; B05D 3/00; G03F 7/20

(52) U.S. Cl. 118/504; 430/325; 427/256

(57) ABSTRACT

According to the embodiments, a template is obtain which is used for imprint of forming a second projection and recess pattern formed of a curing agent on a processing target layer by transferring a first projection and recess pattern onto the curing agent by filling the first projection and recess pattern with the curing agent and curing the curing agent. The template includes the first projection and recess pattern on one surface side of a substrate. The first projection and recess pattern is such that height positions of bottom surfaces of recess portions are approximately the same, and includes two or more types of projection portions whose height from the bottom surfaces of the recess portions is different.

### CROSS-REFERENCE TO RELATED APPLICATIONS

This application is based upon and claims the benefit of priority from Japanese Patent Application No. 2010-145238, filed on Jun. 25, 2010; the entire contents of which are incorporated herein by reference.

### FIELD

Embodiments described herein relate generally to a template, a manufacturing method, and a processing method.

### BACKGROUND

As a method of forming a minute structure in a manufacturing process of a semiconductor, a nanoimprint lithography (NIL) is used. The NIL is a technology of transferring a pattern onto resist by bringing a unit-magnification template (hereinafter, referred to as template) on which a minute pattern that is the same size as a feature size is formed by an electron beam (EB) exposure or the like into contact with a processing target substrate to which the resist is applied.

In the NIL, the template having a projection and recess pattern on its surface is brought into contact with a processing target substrate to which resist liquid is applied. The recess portion of the template is filled with the resist liquid by capillary action. When forming a large-area projection portion of resist on the processing target substrate by using such NIL, the area of the recess portion of the template needs to be large.

However, if the area of the recess portion of the template is large, when the portion around the projection portion is widely spread such as the case where the projection portion of the template is a pillar pattern, the capillary action is difficult to work, so that rising of the liquid surface of the resist liquid is slow.

Consequently, it takes time to fill the recess portion of the template with the resist liquid. In the case where the projection portion of the template is a pillar pattern, the recess portion pattern of the resist is a hole pattern and a hole pattern is formed on the processing target substrate by the processing using this resist pattern.

Moreover, when the area of the recess portion of the template is large, gas present in the recess portion is difficult to release at the time of filling with the resist liquid and therefore it takes time to fill the recess portion with the resist liquid, and a filling failure of the resist liquid occurs easily. The filling failure of the resist liquid results in a shape failure of the projection portion pattern of the resist and affects processing using the formed pattern. In this manner, in the NIL, it is difficult to efficiently form a large-area projection portion with high accuracy.

### BRIEF DESCRIPTION OF THE DRAWINGS

FIG. 1A to FIG. 1J are cross-sectional views illustrating one example of a manufacturing method of a template according to a first embodiment;

FIG. 2A and FIG. 2B are diagrams illustrating a template according to the first embodiment;

FIG. 3A to FIG. 3G are cross-sectional views schematically illustrating an imprint method and a processing method according to the first embodiment;

FIG. 4A to FIG. 4C are top views schematically illustrating the imprint method and the processing method according to the first embodiment;

FIG. 5 is a diagram explaining an anisotropic etching condition with respect to a processing target layer according to the first embodiment;

FIG. 6A and FIG. 6B are diagrams illustrating a template according to a comparison example;

FIG. 7 is a cross-sectional view schematically illustrating an imprint method using the template according to the comparison example;

FIG. 8A and FIG. 8B are diagrams illustrating a design pattern of a substrate according to a second embodiment;

FIG. 9A and FIG. 9B are diagrams illustrating a template according to the second embodiment; and

FIG. 10A to FIG. 10D are cross-sectional views schematically illustrating an imprint method and a processing method according to the second embodiment.

### DETAILED DESCRIPTION

In general, according to embodiments, a template is obtain which is used for imprint of forming a second projection and recess pattern formed of a curing agent on a processing target layer by transferring a first projection and recess pattern onto the curing agent by filling the first projection and recess pattern with the curing agent and curing the curing agent. The template includes the first projection and recess pattern on one surface side of a substrate. The first projection and recess pattern is such that height positions of bottom surfaces of recess portions are approximately the same, and includes two or more types of projection portions whose height from the bottom surfaces of the recess portions is different.

The embodiments of a template, a manufacturing method, and a processing method will be explained below in detail with reference to the drawings. The present invention is not limited to the following description and can be appropriately modified within a range without departing from the scope of the present invention. In the drawings illustrated below, the scale of each member is different from a realistic one in some cases for easy understanding. The same thing can be said between the drawings. Moreover, hatching is applied even to a plan view in some cases to make the drawing more visible.

### First Embodiment

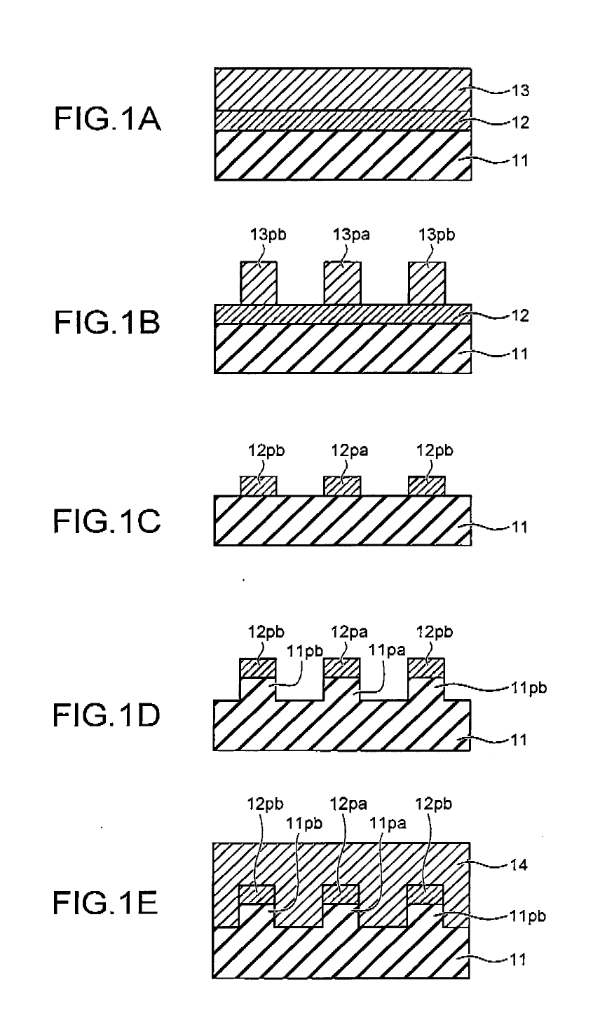

In the following, a process of a nanoimprint lithography (NIL) according to the first embodiment is explained. First, a template substrate (hereinafter, template) used in the NIL is manufactured. FIG. 1A to FIG. 1J are cross-sectional views illustrating one example of a manufacturing method of a template according to the first embodiment. First, a chrome (Cr) film 12 is formed on one surface of, for example, an approximately rectangular quartz substrate 11 and resist 13 is applied to the chrome film 12 (FIG. 1A).

Next, an electron beam (EB) writing is performed on the resist 13, for example, by a circular pattern, and thereafter a development process is performed. Consequently, a resist pattern 13p that is a cylindrical pillar pattern is formed on the chrome film 12 (FIG. 1B). The resist pattern 13p includes two types of patterns, i.e., a main resist pattern 13pa and a dummy resist pattern 13pb.

Next, after performing a visual inspection, a dry etching is performed as an anisotropic etching on the chrome film 12 with the resist pattern 13p as an etching mask, and thereafter the resist pattern 13p is stripped (FIG. 1C). Consequently, a Cr film pattern 12p on which the patterns of the resist pattern 13p are transferred is formed on the quartz substrate 11. The Cr film pattern 12p includes two types of patterns, i.e., a main Cr film pattern 12pa corresponding to the main resist pattern 13pa and a dummy Cr film pattern 12pb corresponding to the dummy resist pattern 13pb.

Next, a dry etching is performed as an anisotropic etching on the quartz substrate 11 with the Cr film pattern 12p as an etching mask. Consequently, a cylindrical quartz pattern 11p on which the patterns of the Cr film pattern 12p are transferred is formed on the surface of the quartz substrate 11 (FIG. 1D). The quartz pattern 11p includes two types of patterns, i.e., a main quartz pattern 11pa corresponding to the main Cr film pattern 12pa and a dummy quartz pattern 11pb corresponding to the dummy Cr film pattern 12pb. The main quartz pattern 11pa and the dummy quartz pattern 11pb have approximately the same height.

Next, after checking the EB writing position and the processing dimension, resist 14 is applied again to the quartz substrate 11 (FIG. 1E). Next, the ED writing is performed on the resist 14 so that only the main Cr film pattern 12pa and the main quartz pattern 11pa are covered by the resist 14, and thereafter a development process is performed. Consequently, a resist pattern 14p, which covers only the main Cr film pattern 12pa and the main quartz pattern 11pa, is formed (FIG. 1F).

Next, a dry etching is performed on the dummy Cr film patterns 12pb with the resist pattern 14p as an etching mask to remove the dummy Cr film patterns 12pb (FIG. 1G). Thereafter, the resist pattern 14p is stripped (FIG. 1H). Consequently, the main Cr film pattern 12pa remains on the main quartz pattern 11pa.

Next, a dry etching is performed as an anisotropic etching on the quartz substrate 11 with the main Cr film pattern 12pa as an etching mask (FIG. 1I). With this etching, the recess portions of the quartz pattern 11p are further engraved. The surfaces of the dummy quartz patterns 11pb are also removed by the same depth. Consequently, the depth position (height) of the recess portions of the quartz pattern 11p becomes approximately constant in the thickness direction of the quartz substrate 11, however, the height of the dummy quartz patterns 11pb becomes different from that of the main quartz pattern 11pa. In the height of the quartz substrate 11 in the thickness direction, i.e., the height from the recess portion of the quartz pattern 11p, the main quartz pattern 11pa is higher than the dummy quartz pattern 11pb.

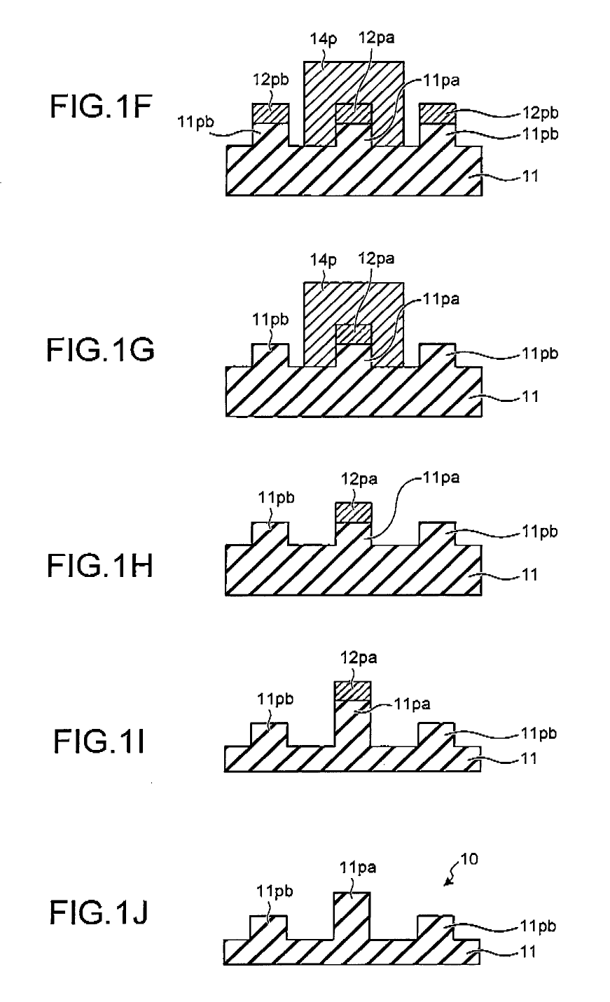

Next, the quartz substrate 11 is cleaned after removing the main Cr film pattern 12pa. Consequently, a template 10 for nanoimprint in which a first projection and recess pattern is formed is completed. The first projection and recess pattern is formed such that the height positions of the bottom surfaces of the recess portions are approximately the same, and includes the main quartz pattern 11pa having a higher height from the bottom surface of the recess portion and the dummy quartz patterns 11pb whose height from the bottom surface of the recess portion is lower than the main quartz pattern 11pa (FIG. 1J). FIG. 2A and FIG. 2B are diagrams illustrating the completed template 10, in which FIG. 2A is a cross-sectional view of the template 10 and FIG. 2B is a top view of the template 10. FIG. 2A is a cross-sectional view taken along line A-A in FIG. 2B.

The main quartz pattern 11pa is a pattern to be transferred onto a processing target layer and is a projection pattern corresponding to a pattern by which the processing target layer is recessed in the processing to the processing target layer with the pattern formed by the NIL using the template 10 as a mask to be described later. The main quartz pattern 11pa is, for example, a cylindrical pattern for forming a hole pattern (main pattern) necessary for circuit operation on a semiconductor substrate. On the other hand, the dummy quartz pattern 11pb is a projection pattern that is transferred onto a resist pattern in the NIL using the template 10 and is not transferred onto the processing target layer in the processing using the resist pattern as described later. The dummy quartz patterns 11pb are provided to correspond to the region in which the processing target layer is not processed in the processing using the resist pattern. The dummy quartz pattern 11pb is, for example, a cylindrical pattern for forming a dummy pattern unnecessary for circuit operation on a semiconductor substrate.

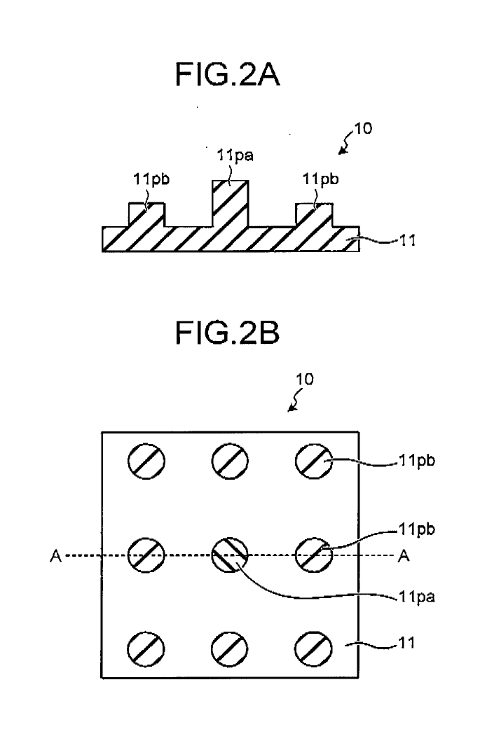

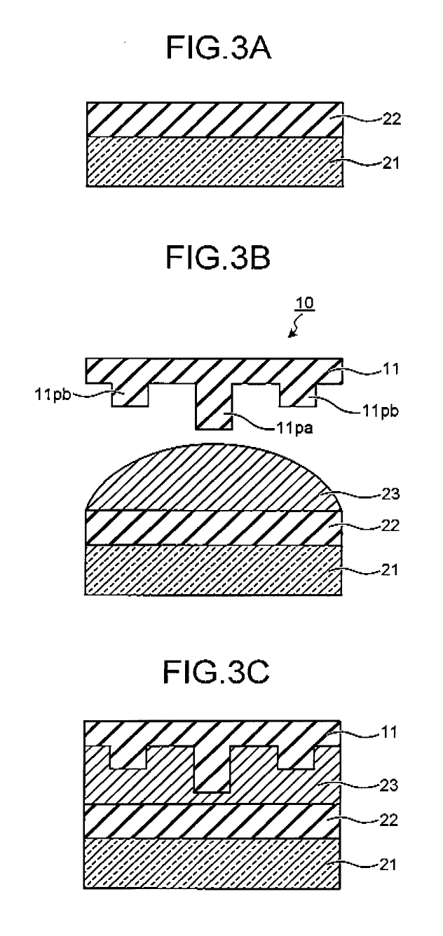

Next, a nanoimprint method and a processing method using the template 10 are explained with reference to FIG. 3A to FIG. 3G and FIG. 4A to FIG. 4C. FIG. 3A to FIG. 3G are cross-sectional views schematically illustrating the imprint method and the processing method using the template 10 according to the first embodiment. FIG. 4A to FIG. 4C are top views schematically illustrating the imprint method and the processing method using the template 10 according to the first embodiment. Although FIG. 4A to FIG. 4C are top views, hatching is applied thereto to make the drawings more visible.

First, a substrate 21 formed of silicon is prepared. A processing target layer 22 formed of a silicon oxide film is formed on one surface of the substrate 21 (FIG. 3A). Next, a photo-curing agent 23 is applied to the processing target layer 22. Next, the template 10 is arranged at a predetermined position over the substrate 21 so that the formation surface of the quartz pattern 11p faces the pattern-formation target surface of the substrate 21 in parallel (FIG. 33 and FIG. 4A). FIG. 4A is a top view of the template 10 as viewed from the top. FIG. 3B is a cross-sectional view taken along line B-B in FIG. 4A.

Next, the template 10 is lowered to bring the formation surface of the quartz pattern 11p of the template 10 into contact with the photo-curing agent 23 on the processing target layer 22 on the substrate 21 (FIG. 3C). After the template 10 comes into contact with the photo-curing agent 23, the template 10 is lowered by its own weight. When the template 10 is moved closer to the photo-curing agent 23, the photo-curing agent 23 enters into the quartz pattern 11p of the template 10 by capillary action. In the template 10, the dummy quartz patterns 11pb are arranged in a matrix manner near the main quartz pattern 11pa, so that the capillary action works easily. Therefore, the recess portions (portions around the main quartz pattern 11pa and the dummy quartz patterns 11pb) of the template 10 are filled with the photo-curing agent 23 in a short time sufficiently.

In this state, the photo-curing agent 23 is irradiated with ultraviolet light via the template 10 by a not-shown light source, so that the photo-curing agent 23 is cured. After the photo-curing agent 23 is sufficiently cured to become resist, the template 10 is raised (FIG. 3D). Consequently, a resist pattern 23p as a second projection and recess pattern on which the shape of the quartz pattern 11p of the template 10 is transferred is formed on the processing target layer 22 on the substrate 21.

The resist pattern 23p includes a recess portion (hole pattern) 23pa corresponding to the main quartz pattern 11pa having a higher height in the quartz pattern 11p of the template 10 and recess portions (hole patterns) 23pb corresponding to the dummy quartz patterns 11pb having a lower height in the quartz pattern 11p of the template 10. Resist remains also in the recess portions (the recess portions 23pa and 23pb) of the resist pattern 23p corresponding to the projection portions of the template.

The film thickness of this residual portion of the resist is typically called Residual Layer Thickness (RLT). The main quartz pattern 11pa and the dummy quartz pattern 11pb have different heights, so that difference occurs in a film thickness (RLT) 24 of the residual portions of the recess portions of the resist pattern 23p in the plane of the substrate 21.

The RLT 24 includes an RLT 24a at the position of the recess portion 23pa and an RLT 24b at the position of the recess portion 23pb. The RLT 24a becomes thinner than the RLT 24b. Therefore, in the height of the recess portion of the resist pattern 23p from the surface of the processing target layer 22, the recess portion 23pb is higher than the recess portion 23pa by the difference of the RLT (RLT 24b-RLT 24a).

Next, an anisotropic etching, for example, by a dry etching is performed on the processing target layer 22 with the resist pattern 23p as an etching mask. In the initial stage of the anisotropic etching, in the projection portion region of the resist pattern 23p, the resist pattern 23p is etched and thus the height thereof becomes low. Moreover, in the region of the recess portion 23pa in which the RLT is thin, the residual portion of the resist pattern 23p is eliminated by etching. On the other hand, in the region of the recess portion 23pb in which the RLT is thick, the residual portion of the resist pattern 23p is etched and thus the RLT becomes thin, however, the residual portion remains (FIG. 3E and FIG. 4B). FIG. 4B is a top view of the substrate 21 as viewed from the top. FIG. 3E is a cross-sectional view taken along line C-C in FIG. 4B.

When etching further proceeds, in the region of the recess portion 23pa, an anisotropic etching of the processing target layer 22 is performed with the resist pattern 23p as an etching mask, whereby the processing target layer 22 is processed into a shape in which the pattern of the recess portion 23pa is transferred. In the region of the recess portion 23pa in which the RLT is thin, the recess portion of the pattern of the processing target layer 22 is eliminated by etching. In the region of the recess portion 23pb in which the RLT is thick, the resist pattern 23p is etched and the RLT becomes thin, however, the residual portion remains, so that the processing target layer 22 is not etched (FIG. 3F). In other words, although the processing target layer 22 is processed in the region of the recess portion 23pa in which the RLT is thin, the processing target layer 22 is not processed in the region of the recess portions 23pb in which the RLT is thick due to the presence of the resist pattern 23p.

Finally, a processing target layer pattern 22p is obtained by removing the resist pattern 23p. In the processing target layer pattern 22p, only the region of the recess portion 23pa in which the RLT is thin is processed and a large-area projection pattern is formed in the region therearound (FIG. 3G and FIG. 4C). FIG. 4C is a top view of the substrate 21 as viewed from the top. FIG. 3G is a cross-sectional view taken along line D-D in FIG. 4C. In other words, as shown in FIG. 4C, the processing target layer pattern 22p is obtained, in which a hole pattern 22pa is formed only in the portion corresponding to the recess portion 23pa in the large-area processing target layer 22. The hole pattern 22pa is a pattern corresponding to the main quartz pattern 11pa of the template 10.

In the anisotropic etching of the processing target layer 22 with the resist pattern 23p as an etching mask, a processing condition is used in which the patterns of the recess portions 23pb in which the RLT is thick are not transferred onto the processing target layer 22. Put another way, processing is performed under such condition that, at the time of completion of the processing of the processing target layer 22, the resist pattern 23p remains in the region of the recess portions 23pb in which the RLT is thick.

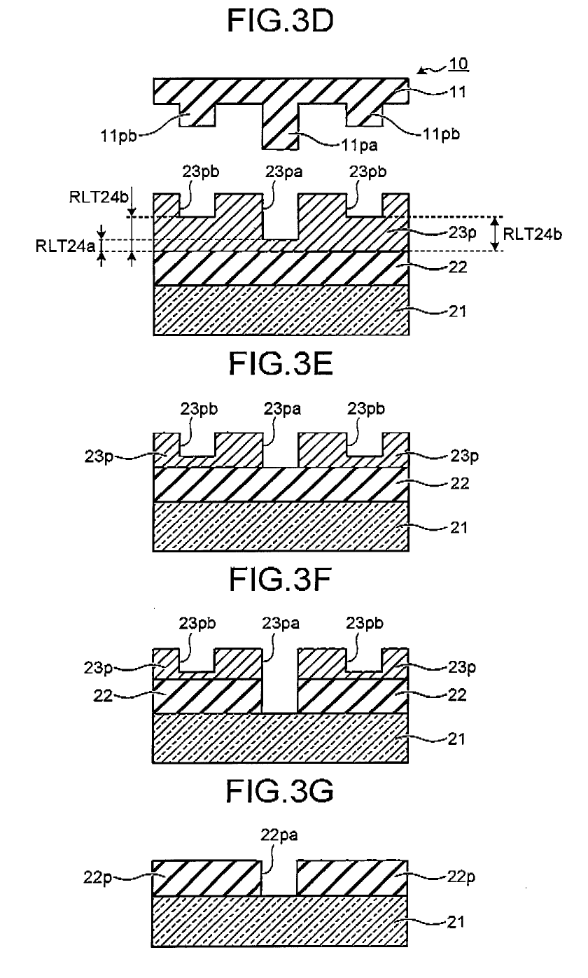

For example, FIG. 5 is a diagram explaining an anisotropic etching condition with respect to the processing target layer 22, and illustrates the state in which the residual portion of the resist pattern 23p is eliminated by etching in the region of the recess portion 23pa in which the RLT is thin (corresponding to the time point of FIG. 3E). The case of processing from this state into the finished state shown by dotted lines in FIG. 5 is considered.

The thickness by which the resist pattern 23p is processed to become the finished state in the region of the recess portions 23pb in which the RLT is thick is d1, and the thickness by which the processing target layer 22 is processed to become the finished state in the region of the recess portion 23pa in which the RLT is thin is d2. The etch rate of the resist pattern 23p is r1, the etch rate of the processing target layer 22 is r2, and the etching time is t.

In this case, because t×r1<d2 and t×r2=d2, t=(d2/r2×r2 is satisfied. Consequently, (r1/r2)<(d1/d2) is derived. That is, processing is performed under the condition where the ratio (r1/r2) of the etch rate of the resist pattern 23p to the processing target layer 22 is smaller than the ratio (d1/d2) of the processing thickness of the resist pattern 23p to the processing target layer 22. When etching is performed under such condition, in the anisotropic etching to the processing target layer 22 with the resist pattern 23p as an etching mask, processing can be performed without transferring the patterns of the recess portions 23pb in which the RLT is thick onto the processing target layer 22.

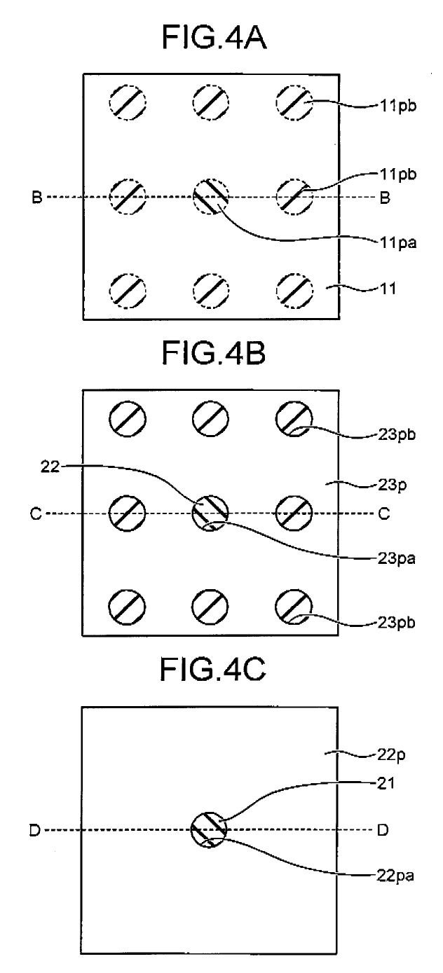

Next, a nanoimprint method and a processing method using a template according to a comparison example are explained. FIG. 6A and FIG. 6B are diagrams illustrating a template 110 according to the comparison example, in which FIG. 6A is a cross-sectional view and FIG. 6B is a top view. FIG. 6A is a cross-sectional view taken along line E-E of FIG. 6B. The template 110 in the comparison example is a template used in the NIL for forming hole patterns in the large-area processing target layer 22 same as the above embodiment. The template 110 includes two cylindrical pillar patterns 111a on one surface of a quartz substrate 111. However, a dummy pattern corresponding to the dummy quartz pattern 11pb in the above embodiment is not present around the pillar patterns 111a.

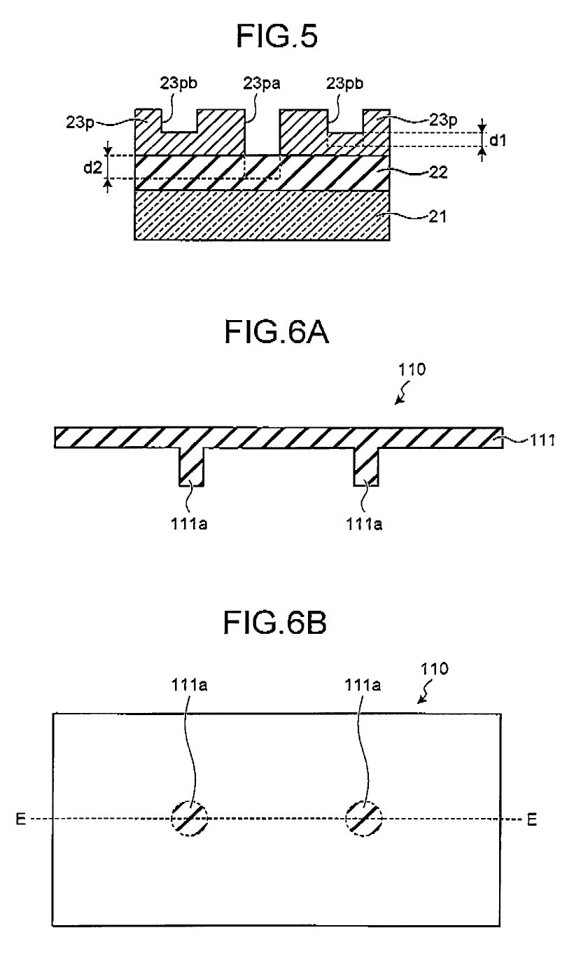

When performing the NIL using such template 110, because a portion around the pillar patterns 111a is widely spread, the capillary action is difficult to work at the time of filling with the photo-curing agent 23 and the rising of the liquid surface is slow. Consequently, it takes time to fill the recess portions (portions around the pillar patterns 111a) of the template 110 with the photo-curing agent 23. Moreover, gas present in the recess portions (portions around the pillar patterns 111a) at the time of filling with the photo-curing agent 23 is difficult to release and it takes time to fill the recess portion with the resist liquid, and furthermore, gas collects on one surface of the template 110 as shown in FIG. 7 to form air bubbles 120, whereby the filling failure of the recess portions with the photo-curing agent 23 occurs easily. The filling failure of the photo-curing agent 23 leads to a shape failure of the projection portion of the resist pattern and subsequent processing is also affected. FIG. 7 is a cross-sectional view schematically illustrating the imprint method using the template 110 according to the comparison example.

According to the above first embodiment, the template 10 is formed such that the height positions of the bottom surfaces of the recess portions are approximately the same, and includes the main quartz pattern 11pa and the dummy quartz patterns 11pb as two or more types of projection portions with different heights from the bottom surface of the recess portion. The main quartz pattern 11pa is a projection portion corresponding to a pattern by which the processing target layer 22 is recessed in the processing to the processing target layer 22 by using the resist pattern 23p as a mask. The dummy quartz pattern 11pb is a projection portion that is lower in height from the bottom surface of the recess portion than the main quartz pattern 11pa and corresponds to the region in which the processing target layer 22 is not processed in the processing to the processing target layer 22 by using the resist pattern 23p as a mask.

The NIL is performed by using the template 10 in which the height positions of the bottom surfaces of the recess portions are approximately the same and which includes projection portions having different heights, thereby forming the resist pattern 23p. Consequently, the RLT in a plurality of the recess portions of the resist pattern 23p can be intentionally made different. Specifically, in the resist pattern 23p, the recess portion 23pa in which the RLT is thin is formed to correspond to the main quartz pattern 11pa and the recess portions 23pb in which the RLT is thick are formed to correspond to the dummy quartz patterns 11pb.

Then, the anisotropic etching of the processing target layer 22 is performed with the resist pattern 23p as a mask under the processing condition in which the patterns of the recess portions 23pb in which the RLT is thick are not transferred onto the processing target layer 22. Consequently, it is possible to transfer only the pattern of the recess portion 23pa, in which the RLT is thin and which corresponds to the main quartz pattern 11pa, onto the processing target layer 22. On the other hand, the patterns of the recess portions 23pb are not transferred onto the processing target layer 22, so that the large-area projection pattern is formed in a region except for the region in which the pattern of the recess portion 23pa is transferred in the processing target layer 22.

Moreover, according to the first embodiment, because the dummy quartz patterns 11pb are provided around the main quartz pattern 11pa of the template 10, the capillary action works easily at the time of filling with the photo-curing agent 23. Therefore, the recess portions (portions around the main quartz pattern 11pa and the dummy quartz patterns 11pb) of the template 10 can be filled with the photo-curing agent 23 in a short time, and moreover the filling failure of the photo-curing agent 23 can be significantly reduced.

Therefore, according to the first embodiment, it is possible to form the hole pattern 22pa in the processing target layer 22 and form the large-area projection pattern in a region therearound accurately and efficiently by a simple method. For example, it is possible to form the small-area hole pattern 22pa in the large-area processing target layer 22 on a semiconductor substrate and form the large-area projection pattern in a region therearound accurately and efficiently by a simple method, by applying the above described embodiment.

### Second Embodiment

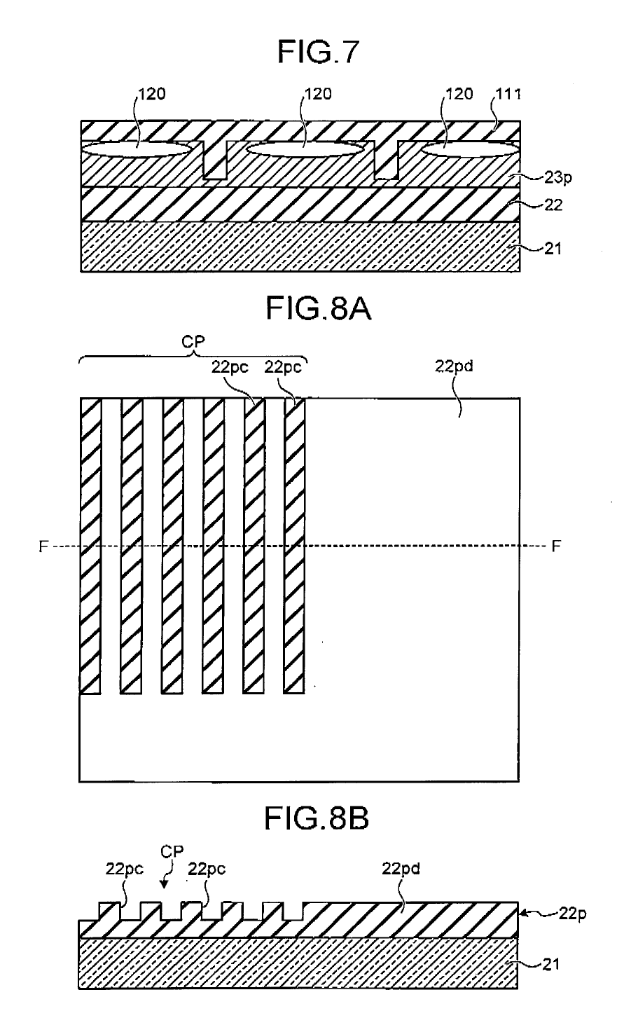

In the second embodiment, explanation is given for the method of performing processing of a design pattern as shown in FIG. 8A and FIG. 8B. FIG. 8A and FIG. 8B are diagrams illustrating the design pattern of the substrate 21 according to the second embodiment, in which FIG. 8A is a top view and FIG. 8B is a cross-sectional view. FIG. 8B is a cross-sectional view taken along line F-F in FIG. 8A. In the design pattern shown in FIG. 8A and FIG. 8B, as the processing target layer pattern 22p formed by processing the processing target layer on the substrate 21, an unpatterned peripheral region (projection pattern) 22pd having a large area is provided around of a line and space (L/S) circuit pattern CP including recess patterns 22pc.

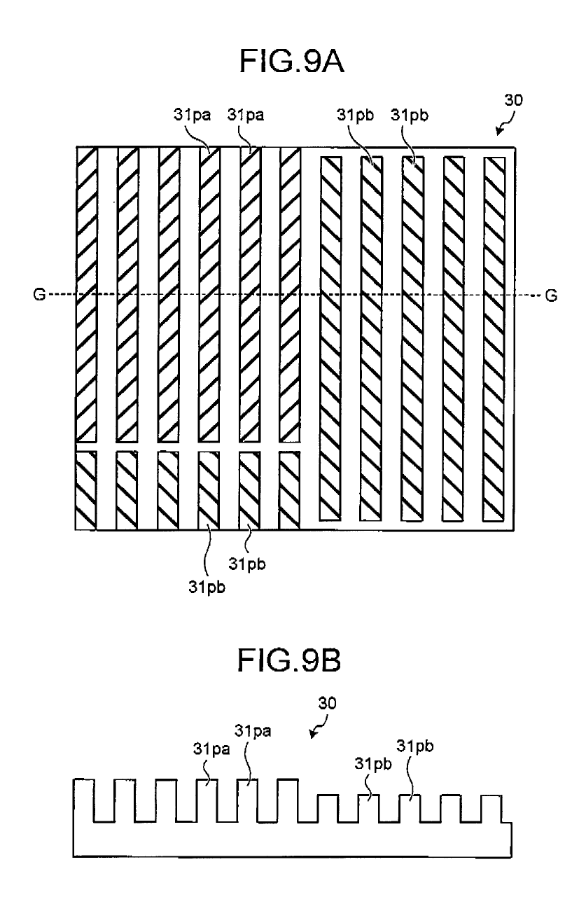

FIG. 9A and FIG. 9B are diagrams illustrating a template 30 according to the second embodiment. FIG. 9A is a top view of the template 30 and FIG. 9B is a cross-sectional view of the template 30. FIG. 93 is a cross-sectional view taken along line G-G in FIG. 9A. The template 30 is a template for NIL in which the height positions of the bottom surfaces of the recess portions are approximately the same and which includes main quartz patterns 31pa having a higher height from the bottom surface of the recess portion and dummy quartz patterns 31pb whose height from the bottom surface of the recess portion is lower than the main quartz patterns 31pa (hereinafter, the main quartz patterns 31pa and the dummy quartz patterns 31pb are collectively called a projection and recess pattern 31p in some cases). The template 30 can be manufactured by a method similar to the method explained with reference to FIG. 1A to FIG. 1J in the first embodiment.

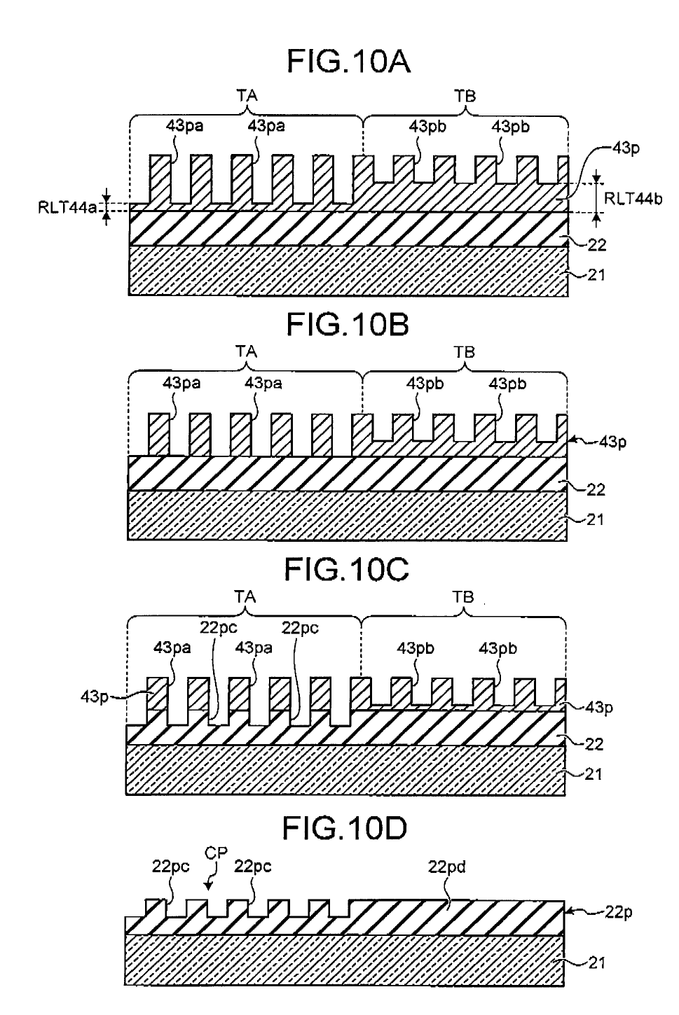

Next, a nanoimprint method and a processing method using the template 30 are explained with reference to FIG. 10A to FIG. 10D. FIG. 10A to FIG. 10D are cross-sectional views schematically illustrating the imprint method and the processing method using the template 30 according to the second embodiment.

First, a process corresponding to FIG. 3A to FIG. 3D in the first embodiment is performed by using the template 30, thereby forming a resist pattern 43p, on which the shape of the projection and recess pattern 31p of the template 30 is transferred to have an L/S pattern, on the processing target layer 22 on the substrate 21 (FIG. 10A). The resist pattern 43p includes recess portions 43pa corresponding to the main quartz patterns 31pa having a higher height in the projection and recess pattern 31p of the template 30 and recess portions 43pb corresponding to the dummy quartz patterns 31pb having a lower height in the projection and recess pattern 31p of the template 30. In the resist pattern 43p, the region including the recess portions 43pa is a formation region TA of the L/S circuit pattern CP and the region including the recess portions 43pb is a formation region TB of the unpatterned peripheral region (projection pattern) 22pb.

Resist remains also in the recess portions of the resist pattern 43p. The main quartz pattern 31pa and the dummy quartz pattern 31pb have different heights, so that difference occurs in a film thickness (RLT) 44 of the residual portions of the recess portions of the resist pattern 43p in the plane of the substrate 21. The RLT 44 includes an RLT 44a at the position of the recess portion 43pa and an RLT 44b at the position of the recess portion 43pb. The RLT 44a becomes thinner than the RLT 44b. Therefore, in the height of the recess portion of the resist pattern 43p from the surface of the processing target layer 22, the recess portion 43pb is higher than the recess portion 43pa by the difference of the RLT (RLT 44b-RLT 44a).

Next, an anisotropic etching, for example, by a dry etching is performed on the processing target layer 22 with the resist pattern 43p as an etching mask. In the initial stage of the anisotropic etching, in the projection portion region of the resist pattern 43p, the resist pattern 43p is etched and thus the height thereof becomes low. Moreover, in the region of the recess portion 43pa in which the RLT is thin, the residual portion of the resist pattern 43p is eliminated by etching. On the other hand, in the region of the recess portion 43pb in which the RLT is thick, the residual portion of the resist pattern 43p is etched and thus the RLT becomes thin, however, the residual portion remains (FIG. 10B).

When etching further proceeds, in the region of the recess portions 43pa, etching of the processing target layer 22 is performed with the resist pattern 43p as an etching mask, whereby the processing target layer 22 is processed into a shape in which the patterns of the recess portions 43pa are transferred. In the region of the recess portions 43pa in which the RLT is thin, the processing target layer 22 is etched to a predetermined depth. In the region of the recess portions 43pb in which the RLT is thick, the resist pattern 43p is etched and the RLT becomes thin, however, the residual portion remains, so that the processing target layer 22 is not etched (FIG. 10C). In other words, although the processing target layer 22 is processed in the region of the recess portions 43pa in which the RLT is thin, the processing target layer 22 is not processed in the region of the recess portions 43pb in which the RLT is thick due to the presence of the resist pattern 43p.

In the anisotropic etching of the processing target layer 22 with the resist pattern 43p as an etching mask, a processing condition is used in which the patterns of the recess portions 43pb in which the RLT is thick are not transferred onto the processing target layer 22. Put another way, processing is performed under such condition that, at the time of completion of the processing of the processing target layer 22, the resist pattern 43p remains in the region of the recess portions 43pb in which the RLT is thick.

Finally, the processing target layer pattern 22p is obtained by removing the resist pattern 43p. In the processing target layer pattern 22p, only the region of the recess portions 43pa in which the RLT is thin is processed and a large-area projection pattern is formed in the region therearound (FIG. 10D). The substrate 21 having the design pattern shown in FIG. 8A and FIG. 8B can be manufactured by performing the above process.

According to the above second embodiment, the resist pattern 43p is formed by performing the NIL using the template 30 in which the height positions of the bottom surfaces of the recess portions are approximately the same and which includes the main quartz patterns 31pa having a higher height from the bottom surface of the recess portion and the dummy quartz patterns 31pb whose height from the bottom surface of the recess portion is lower than the main quartz patterns 31pa. Consequently, the RLT in a plurality of the recess portions of the resist pattern 43p can be intentionally made different. Specifically, in the resist pattern 43p, the recess portions 43pa in which the RLT is thin are formed to correspond to the main quartz patterns 31pa and the recess portions 43pb in which the RLT is thick are formed to correspond to the dummy quartz patterns 31pb.

Then, the anisotropic etching of the processing target layer 22 is performed with the resist pattern 43p as a mask under the processing condition in which the patterns of the recess portions 43pb in which the RLT is thick are not transferred onto the processing target layer 22. Consequently, it is possible to transfer only the patterns of the recess portions 43pa, in which the RLT is thin and which correspond to the main quartz patterns 31pa, onto the processing target layer 22 with high accuracy. On the other hand, the patterns of the recess portions 43pb are not transferred onto the processing target layer 22, so that the large-area projection portion is formed in a region except for the region in which the patterns of the recess portions 43pa are transferred in the processing target layer 22.

Moreover, according to the second embodiment, because the dummy quartz patterns 31pb are provided around the main quartz patterns 31pa of the template 30, the capillary action works easily at the time of filling with the photo-curing agent. Therefore, the recess portions (portions around the main quartz patterns 31pa and the dummy quartz patterns 31pb) of the template 30 can be filled with the photo-curing agent in a short time, and the filling failure of the photo-curing agent can be significantly reduced.

Therefore, according to the second embodiment, it is possible to form the unpatterned peripheral region (projection pattern) 22pd having a large area around the L/S circuit pattern CP accurately and efficiently by a simple method.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template that is used for imprint of forming a second projection and recess pattern formed of a curing agent on a processing target layer by transferring a first projection and recess pattern onto the curing agent by filling the first projection and recess pattern with the curing agent and curing the curing agent, the template comprising:
the first projection and recess pattern on one surface side of a substrate, wherein
the first projection and recess pattern is such that height positions of bottom surfaces of recess portions are approximately same, and includes two or more types of projection portions whose height from the bottom surfaces of the recess portions is different.

2. The template according to claim 1, wherein
the two or more types of the projection portions includes
a first projection portion that corresponds to a pattern by which the processing target layer is recessed in processing to the processing target layer using the second projection and recess pattern as a mask, and
a second projection portion, whose height from the bottom surfaces of the recess portions is lower than the first projection portion and which corresponds to a region in which the processing target layer is not processed in processing to the processing target layer using the second projection and recess pattern as a mask.

3. The template according to claim 2, wherein a formation area of the first projection portion is smaller than an area of a region in which the second projection portion is formed.

4. The template according to claim 3, wherein the second projection portion includes a plurality of second projection portions that are arranged to surround the first projection portion.

5. The template according to claim 3, wherein the second projection portion includes a plurality of second projection portions that are arranged in a region in which the first projection portion is not formed on one surface side of the substrate.

6. A method of manufacturing a template that is used for imprint of forming a second projection and recess pattern formed of a curing agent on a processing target layer by transferring a first projection and recess pattern onto the curing agent by filling the first projection and recess pattern with the curing agent and curing the curing agent, the method comprising;
forming a projection and recess pattern that includes a plurality of projection portions having approximately same height by processing one surface side of a template substrate; and
forming the first projection and recess pattern that includes two or more types of projection portions having a different height by processing part of the projection portions to have a lower height.

7. The method of manufacturing a template according to claim 6, further comprising:
forming a mask pattern on one surface of the template substrate;
forming the projection and recess pattern that includes a plurality of projection portions having approximately same height on the template substrate by etching one surface side of the template substrate with the mask pattern as a mask;
removing the mask pattern while leaving part of the mask pattern; and
forming the first projection and recess pattern that includes two or more types of projection portions having a different height by etching one surface side of the template substrate with the mask pattern remaining on the template substrate as a mask.

8. The method of manufacturing a template according to claim 7, further comprising forming a first projection portion that corresponds to a pattern by which the processing target layer is recessed in processing to the processing target layer using the second projection and recess pattern as a mask, and a second projection portion, whose height from bottom surfaces of recess portions is lower than the first projection portion and which corresponds to a region in which the processing target layer is not processed in processing to the processing target layer using the second projection and recess pattern as a mask, as the two or more types of the projection portions.

9. The method of manufacturing a template according to claim 8, wherein a formation area of the first projection portion is smaller than an area of a region in which the second projection portion is formed.

10. The method of manufacturing a template according to claim 9, wherein the second projection portion includes a plurality of second projection portions that are formed to surround the first projection portion.

11. The method of manufacturing a template according to claim 9, wherein the second projection portion includes a plurality of second projection portions that are arranged in a region in which the first projection portion is not formed on one surface side of the substrate.

12. A processing method comprising:
applying a curing agent to a processing target layer;
forming a second projection and recess pattern that includes two or more types of recess portions having a different height position of a bottom surface by transferring a first projection and recess pattern, in which height positions of bottom surfaces of recess portions are approximately same and which includes two or more types of projection portions whose height from the bottom surfaces of the recess portions is different, onto the curing agent by curing the curing agent in a state where the first projection and recess pattern is brought into contact with the curing agent;
separating the first projection and recess pattern from cured curing agent; and
processing the processing target layer under a condition where the curing agent remains on a bottom surface of a recess portion whose height position of a bottom surface is higher in the second projection and recess pattern, by using the second projection and recess pattern as a mask.
